(19) United States
(12) Patent Application Publication
(10) Pub. No.: US 2006/0138574 A1
(43) Pub. Date: Jun. 29, 2006

(54) Capacitive sensor

(75) Inventors: Junichi Saito, Miyagi-ken (JP); Takuo Ito, Miyagi-ken (JP)

Correspondence Address: BEYER WEAVER & THOMAS LLP, P.O. BOX 70250, OAKLAND, CA, 94612-0250, US

(73) Assignee: ALPS ELECTRIC CO., LTD.

(21) Appl. No.: 11/280,681

(22) Filed: Nov. 15, 2005

(30) Foreign Application Priority Data
Dec. 27, 2004 (JP) 2004-377085

(51) Int. Cl. H01L 29/84

(52) U.S. Cl. 257/417

(57) ABSTRACT

A pressure-sensitive capacitive sensor is provided that can easily remove noises delivered from a human body. The capacitive sensor includes a sensor unit having a first substrate where a plurality of vertical wiring lines is formed and a second substrate where a plurality of horizontal wiring lines is formed, the first and second substrates being disposed in a matrix and facing each other with a gap interposed therebetween, and a capacitance at intersections between the vertical wiring lines and the horizontal wiring lines changed in response to an external pressure; and a detecting unit for detecting the change in capacitance at the intersections between the vertical wiring lines and the horizontal wiring lines, and detecting an externally applied pressure distribution based on the detecting result. In this case, a horizontal wiring line 50 for noise detection is disposed on a surface where the horizontal wiring lines are formed in the second substrate.

### BACKGROUND OF THE INVENTION

1. Field of the Invention

The present invention relates to a capacitive sensor, and, more particularly, to a pressure-sensitive capacitive sensor preferably used as a fingerprint sensor.

2. Description of the Related Art

A surface pressure distribution sensor for sensing a fine unevenness is used as a fingerprint sensor or the like. FIG. 17 shows a related art. As shown in FIG. 17, the fingerprint scanning device (i.e. fingerprint sensor) includes a first electrode group 12 consisting of a plurality of verticals extending in a first direction; a second electrode group 14 consisting of a plurality of horizontals extending in a second direction crossing the first direction and disposed on the first electrode group with an interlayer insulating film 13 interposed between the first and second electrode groups; a fingerprint scanning sensor having a surface protective layer 15 made of a dielectric substance disposed on the second electrode group 14; and driving circuits 18 and 19 applying a predetermined voltage to each of the first electrodes 12 and the second electrodes 14 sequentially, and measuring electrostatic capacitances between the electrodes 12 and 14 and the fingerprint in contact with the surface protective layer 15 so as to measure the change in the electrostatic capacitances near intersections between the first electrodes 12 and the second electrodes 14 (See JP-A-2001-46359).

In the fingerprint reading device using the above pressure-sensitive capacitive sensor, noises are flowed into a fingerprint detecting unit from a human body via a finger when the finger is pressed to the fingerprint detecting unit in order to scan the fingerprint.

That is, the noises are flowed in due to parasitic capacitances which occur between the fingerprint and detecting wiring lines at positions where driving wiring lines (vertical electrode) and the detecting wiring lines (horizontal wiring lines) are disposed in a matrix with a vertical gap therebetween and do not cross each other, and the noises cause the degradation of the detecting accuracy.

The pressure-sensitive capacitive sensor in the related art cannot remove the noises flowed in from the human body.

### SUMMARY OF THE INVENTION

The present invention has been finalized in view of the drawbacks inherent in the capacitive sensor in the related art, and it is an advantage of the invention to provide a pressure-sensitive capacitive sensor capable of easily removing noises delivered from a human body.

One aspect of the invention is a pressure-sensitive capacitive sensor, including a sensor unit having a first substrate 20 where a plurality of vertical wiring lines 22 is formed; and a second substrate 30 where a plurality of horizontal wiring lines 32 is formed, the first and second substrates being disposed in a matrix and facing each other with a gap therebetween, and the capacitance at the intersections between the vertical wiring lines and the horizontal wiring lines changed according to external pressure; and a detecting unit for detecting the change in the capacitance at the intersections between the vertical wiring lines and the horizontal wiring lines and detecting an externally applied pressure distribution based on the detecting result. In this case, a horizontal wiring line 50 for noise detection is disposed on a surface where the horizontal wiring lines are formed on the second substrate.

In the above pressure-sensitive capacitive sensor, the first substrate where a plurality of horizontal wiring lines is formed and the second substrate where a plurality of vertical wiring lines is formed face each other with a gap therebetween, and the first and second substrates have a matrix formed by the horizontal and vertical wiring lines, and the horizontal wiring line for noise detection is disposed on a surface of the second substrate where the horizontal wiring lines are formed.

In addition, the capacitive sensor includes a sensor unit and a detecting unit, and the sensor unit senses the change in the capacitance at the intersections between the horizontal wiring lines and the vertical wiring lines in response to an externally applied pressure, and the detecting unit detects the change in the capacitance at the intersections between the horizontal wiring lines and the vertical wiring, thereby an externally applied pressure distribution is detected based on the corresponding detecting result.

Therefore, according to the above structure, the area of the horizontal wiring line for noise detection is set almost equal to the sum of the areas of wiring lines (that is, gap areas) where the horizontal wiring lines and the vertical wiring lines do not cross each other, that is, the amount of noises delivered to the horizontal wiring lines from the finger becomes almost equal to the amount of noises delivered to the horizontal wiring line for noise detection from the finger, thereby the amount of capacitances between the finger and the horizontal wiring lines becomes almost equal to the amount of capacitances between the finger and the horizontal wiring line for noise detection when the finger, the detecting target, comes in contact with the sensor unit if the capacitive sensor is used as a fingerprint sensor. As a result, the difference between the amount of noises delivered to each of the horizontal wiring lines and the amount of noises delivered to the horizontal wiring line for noise detection can be taken by signal processing of the detecting unit of the subsequent stage, thereby the noises delivered from a human body can be easily removed.

In addition, the vertical wiring lines are not disposed at a position facing the horizontal wiring line for noise detection in the capacitive sensor.

According to the above capacitive sensor, the vertical wiring lines are not disposed at the position facing the horizontal wiring for noise detection. Therefore, the horizontal wiring line for noise detection does not cross the vertical wiring lines, thereby signal components are not flowed into the horizontal wiring line for noise detection from the vertical wiring lines, and when the capacitive sensor is used as the fingerprint sensor, only noises delivered from a human body by the finger can be detected via the horizontal wiring line for noise detection. Accordingly, the structure of the detecting circuit for carrying out the subsequent signal processing can be simplified.

In addition, in the pressure-sensitive capacitive sensor, the first substrate has flexibility and uses a surface of the first substrate as a contacting surface with a detecting target.

According to the above capacitive sensor, the substrate has flexibility and uses a surface of the first substrate as the contacting surface with the detecting target.

Therefore, in the above construction, when the capacitive sensor is used as fingerprint sensor, the first substrate is deformed in response to the unevenness of the fingerprint of the finger, the detecting target, and the pressure distribution can be detected accurately.

In addition, in the capacitive sensor, the area of the horizontal wiring line for noise detection is equal to the detecting area, the area of one horizontal wiring subtracted by the area, at which the vertical wiring lines and the horizontal wiring lines overlap in a horizontal wiring.

In the above capacitive sensor, the area of the horizontal wiring line for noise detection is set to the detecting area, the area of one horizontal wiring subtracted by the area, at which the vertical wiring lines and the horizontal wiring lines overlap in a horizontal wiring.

Therefore, when the capacitive sensor is used as a fingerprint sensor, regardless of the change in the unevenness of the first substrate (film substrate) by the fingerprint when the finger comes in contact with the sensor unit, the capacitance between the finger and the horizontal wiring lines is almost equal to the capacitance between the finger and the horizontal wiring line for noise detection, and the amount of noises delivered from the finger to the horizontal wiring lines is almost equal to the amount of noises delivered from the finger to the horizontal wiring line for noise detection. As a result, the difference between the amount of noises delivered to each of the horizontal wiring lines and the amount of noises delivered to the horizontal wiring line for noise detection can be taken by signal processing of the detecting unit of the subsequent stage, thereby the noises delivered from a human body can be easily removed.

In addition, according to the pressure-sensitive capacitive sensor, the horizontal wiring line for noise detection has the same form as that of the horizontal wiring lines, and a shield plate for shielding the noise is disposed on the horizontal wiring line for noise detection, and the shield plate is disposed in the first substrate while having an opening for opening the area corresponding to the detecting area of the horizontal wiring line for noise detection.

In the above capacitive sensor, the horizontal wiring line for noise detection is shaped like the horizontal wiring lines on the second substrate, and the shield plate for shielding noises are disposed with the vertical wiring lines in the first substrate. In addition, the shield plate has an opening, through which the area corresponding to the detecting area of the horizontal wiring line for noise detection is exposed.

Therefore, according to the above structure, a wiring width limit (design rule) of the horizontal wiring line for noise detection can be equal to that of the horizontal wiring (detecting wiring) or the vertical wiring (driving wiring), thereby the cost limit can be reduced.

In addition, in the above pressure-sensitive capacitive sensor, the shield plate on the horizontal wiring lines for noise is shaped like a comb having the same pitch as those of the vertical. wiring lines in order to be shaped like the shape of the area where the horizontal wiring and the vertical wiring do not cross each other in the matrix of the horizontal wiring and the vertical wiring, and the area corresponding to the detecting area of the horizontal wiring line for noise detection is exposed.

in the above capacitive sensor, the shield plate on the horizontal wiring lines for noise is shaped like a comb having the same pitch as those of the vertical wiring lines in order to be shaped like the shape of the area where the horizontal wiring and the vertical wiring do not cross each other in the matrix of the horizontal wiring and the vertical wiring, and the area corresponding to the detecting area of the horizontal wiring line for noise detection is exposed.

Therefore, according to the above structure, since the horizontal wiring line for noise detection is shaped very similar to each horizontal wiring, the manner of unevenness of the second substrate (film substrate) near the area of the sensor unit in contact with the finger becomes equal to the manner of unevenness of the other areas when the capacitive sensor is used as a fingerprint sensor, thereby the amount of noises delivered to the horizontal wiring lines (detecting wiring) is closer to the amount of noises delivered to the horizontal wiring line for noise detection, and thus the noise-reducing effect can be improved by the signal processing of the detecting unit. In addition, a discomfort can be removed when the sensor unit is pressed by the finger.

Furthermore, in the above capacitive sensor, the first and second substrates are composed of a single flexible film substrate, and the horizontal and vertical wiring lines are formed on the flexible film substrate. In addition, the flexible film substrate is bent at a predetermined position to make the horizontal wiring lines and the vertical wiring lines cross each other.

Therefore, according to the above structure, the capacitive sensor can be easily assembled, and the manufacturing cost can be reduced.

### BRIEF DESCRIPTION OF THE DRAWINGS

FIG. 1 is a circuit view illustrating an electric structure of a pressure-sensitive capacitive sensor according to the present invention;

FIG. 2 is a cross-sectional view of the pressure-sensitive capacitive sensor of FIG. 1;

FIG. 3 is a view for explaining a usage state of scanning a fingerprint by means of the pressure-sensitive capacitive sensor shown in FIG. 1;

FIG. 4 is a view illustrating states of a vertical wiring and a horizontal wiring of the pressure-sensitive capacitive sensor shown in FIG. 1, a change in capacitance between the vertical wiring and the horizontal wiring when a sensor unit is pressed by a finger, and a change in capacitance between the finger and the horizontal wiring;

FIG. 5 is a plan view and a cross-sectional view illustrating a structure of the pressure-sensitive capacitive sensor according to a first embodiment of the invention;

FIG. 6 is a plan view and a cross-sectional view illustrating a structure of the pressure-sensitive capacitive sensor according to a second embodiment of the invention;

FIG. 7 is a plan view and a cross-sectional view illustrating a structure of the pressure-sensitive capacitive sensor according to a third embodiment of the invention;

FIG. 8 is a plan view and a cross-sectional view illustrating a structure of the pressure-sensitive capacitive sensor according to a fourth embodiment of the invention;

FIG. 9 is a plan view and cross-sectional view illustrating a structure of the pressure-sensitive capacitive sensor in accordance with a fifth embodiment of the present invention;

FIG. 10 is a plan view and a cross-sectional view illustrating a structure of the pressure-sensitive capacitive sensor according to a sixth embodiment of the invention;

FIG. 11 is view illustrating an enlarged A portion of FIG. 10;

FIG. 12 is a cross-sectional view taken along G-G′ wiring of FIG. 11;

FIG. 13 is a view for explaining a basic characteristic of a current conveyor circuit;

FIG. 14 is a circuit view illustrating a structure of a basic detecting circuit using the current conveyor circuit for signal detection;

FIG. 15 is a circuit view illustrating an example of a detecting circuit of the capacitive sensor configured to use a current conveyor circuit according to embodiments of the invention;

FIG. 16 is a circuit view illustrating another example of a detecting circuit of the capacitive sensor configured to use a current conveyor circuit according to the embodiments of the invention; and

FIG. 17 is a cross-sectional view and a plan view illustrating a schematic structure of the fingerprint reading device of the related art.

### DESCRIPTION OF THE PREFERRED EMBODIMENT

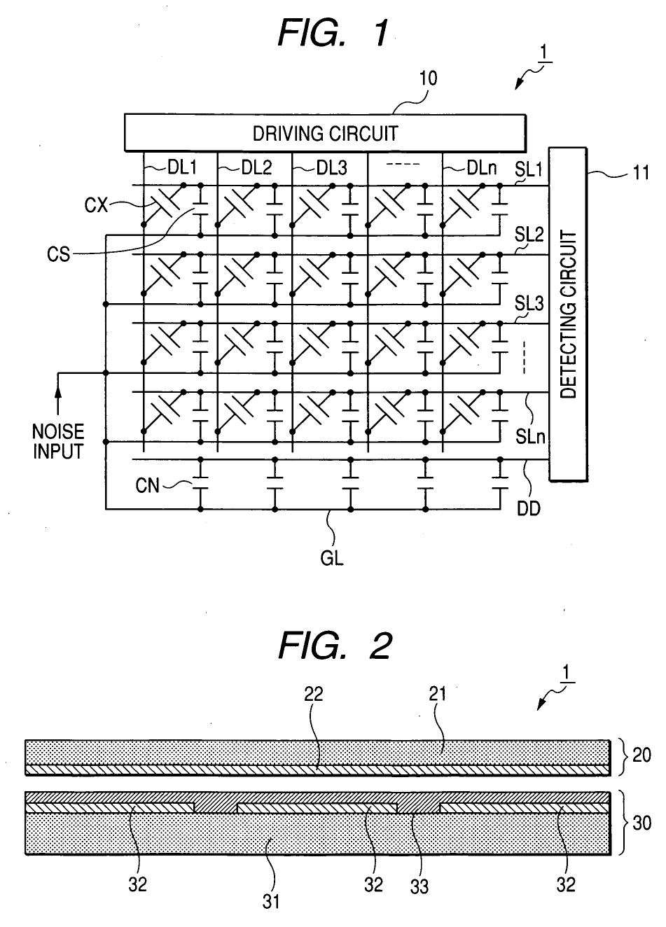

Hereinafter, embodiments of the present invention will be described in detail with reference to the accompanying drawings. The embodiments of the invention describe the pressure-sensitive capacitive sensor applied to a fingerprint sensor. An operation principle of the pressure-sensitive capacitive sensor according to the invention will be described with reference to FIGS. 1 to 4. FIG. 1 conceptually shows an electric structure of the pressure-sensitive capacitive sensor according to the invention. In FIG. 1, the capacitive sensor 1 according to the invention includes vertical wiring lines DL1 to DLn, horizontal wiring lines SL1 to SLn, a horizontal wiring line for noise detection DD, a driving circuit 10 for supplying a driving voltage to the vertical wiring lines DL1 to DLn, and a detecting circuit 11 for detecting signal currents from the horizontal wiring lines SL1 to SLn.

In addition, a capacitance CX is a capacitance for signal-detecting formed between the vertical wiring lines and the horizontal wiring lines, and a capacitance CS is a parasitic capacitance formed between a finger and a gap where the horizontal wiring and the vertical wiring do not cross each other when the fingerprint is scanned. In addition, a capacitance CN is a parasitic capacitance formed between the finger and the horizontal wiring line for signal-detection when the fingerprint is scanned.

FIG. 2 shows a cross-sectional structure of the capacitive sensor 1. In FIG. 2, the vertical wiring lines DL1 to DLn correspond to vertical wiring lines 22, and the horizontal wiring lines SL1 to SLn correspond to horizontal wiring lines 32. In addition, the horizontal wiring line for signal-detecting is not shown in FIG. 2.

The capacitive sensor 1 has a first substrate 20 (film substrate) where a plurality of vertical wiring lines 22 is formed on one surface of a film 21, and a second substrate 30 where a plurality of horizontal wiring lines 32 is formed on a base 31, and the first and second substrates face each other with a gap interposed therebetween. The vertical wiring lines 22 and the horizontal wiring 32 are disposed in a matrix, and the horizontal wiring line for signal-detecting (not shown) is disposed not to cross the vertical wiring lines on the base 31 of the second substrate 30 where the horizontal wiring lines 32 are formed. A reference numeral 33 denotes an insulating layer.

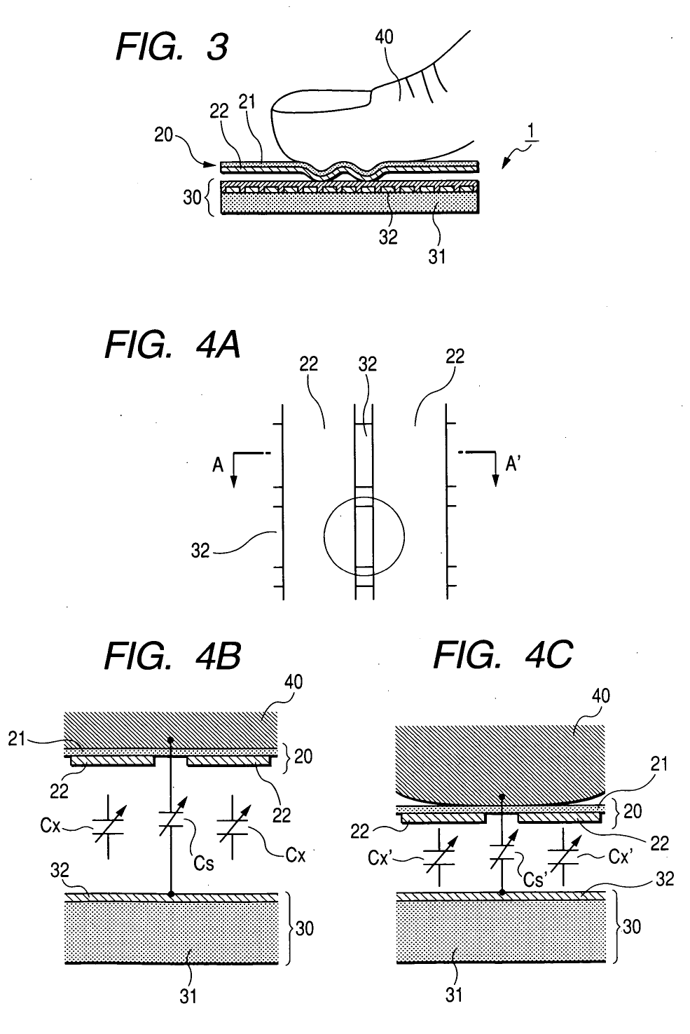

As shown in FIG. 3, when the finger 40 comes in contact with a surface of the first substrate 20 (film substrate) formed at an upper side of the capacitive sensor 1, the first substrate 20 is deformed by an external force added according to the unevenness of the fingerprint of the finger 40, and a space between the first substrate 20 and the second substrate 30 is changed. In addition, the pressure distribution appears as the changes in the capacitance at the intersections between the vertical wiring lines and the horizontal wiring lines, and is detected by the detecting circuit 11.

In the meantime, when the finger 40 comes in contact with the first substrate, noises are flowed into the capacitive sensor 1 from a human body. FIG. 4A shows a state that the vertical wiring 22 and the horizontal wiring 32 are disposed in a matrix in the capacitive sensor 1, and FIGS. 4B and 4C are cross-sectional views taken along line A-A′ of FIG. 4A.

As shown in FIG. 4B, while the finger 40 comes in contact with the film 21 of the first substrate 20, the capacitance for signal-detecting CX is formed between the vertical wiring 22 and the horizontal wiring 32, and the parasitic capacitance CS is concurrently formed between the finger 40 and the gap, that is, the area where the corresponding horizontal wiring 32 of the horizontal wiring lines 32 and the vertical wiring 22 do not cross each other.

Next, while the finger 40 is pressed onto the first substrate 20 as shown in FIG. 4C, the space between the first substrate 20 and the second substrate 30 decreases, which in turn causes the space between the vertical wiring 22 and the horizontal wiring 32 and a distance between the finger 40 and the horizontal wiring 32 to decrease as compared to a case of not pressing the finger 40 onto the first substrate 20, thereby the capacitance for signal-detecting and the parasitic capacitance increase to have values of CX′ and CS′, respectively. Accordingly, the amount of noises delivered from the human body further increase in a case of pressing the finger 40 onto the first substrate 20 as compared to a case of not pressing finger 40 onto the first substrate 20.

In the capacitive sensor 1 of the invention, the horizontal wiring line for noise detection DD is formed not to cross the vertical wiring on the base 31 of the second substrate 30, thereby only the noise delivered from the human body via the parasitic capacitance CN is sensed by the horizontal wiring line for noise detection.

Accordingly, a sum of the parasitic capacitances CN formed between the finger 40 and the horizontal wiring line for noise detection DD is made to be equal to a sum of the parasitic capacitances CS formed between the finger 40 and one horizontal wiring, in other words, the area of the horizontal wiring line for noise detection is set to a detecting area, the area of one horizontal wiring subtracted by the sum of areas, at which the vertical wiring lines and the horizontal wiring lines overlap in a horizontal wiring, thereby noise components delivered from the human body can be removed by taking a difference between the noise component output from the wiring line for noise detection and the output detected from each of the horizontal wiring lines by means of the detecting circuit 11.

### First Embodiment

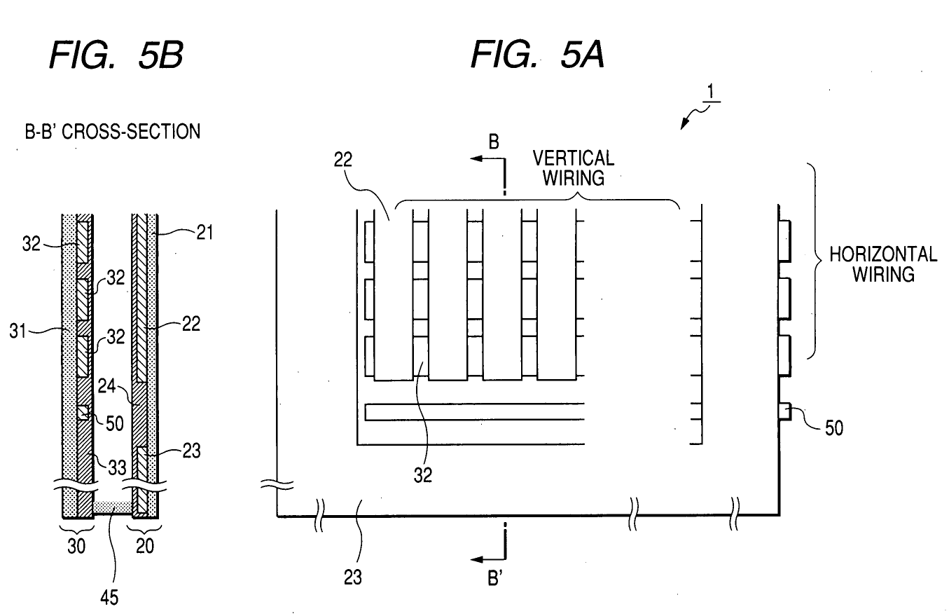

FIG. 5 shows a structure of the pressure-sensitive capacitive sensor according to a first embodiment of the invention. Meanwhile, since the gist of the invention lies in the structure of the capacitive sensor, the gist of the invention is not limited to the present embodiment, and the electric structure is omitted in each embodiment. FIG. 5A is a plan view seen from the first substrate 20 (film shaped substrate) of the capacitive sensor, and FIG. 5B is a cross-sectional view taken along B-B′ line of FIG. 5A. The Same reference numerals are attached to the same members as those of the capacitive sensor shown in FIGS. 2 to 4.

The pressure-sensitive capacitive sensor 1 according to the first embodiment of the invention includes the first substrate 20 where a plurality of vertical wiring lines 22 is formed; and the second substrate 30 where a plurality of horizontal wiring lines 32 is formed. The first and second substrates face each other with a spacer 45 interposed therebetween, and the vertical wiring lines 22 and the horizontal wiring lines 32 are disposed in a matrix. The matrix portion of the vertical wiring lines 22 and the horizontal wiring lines 32 constitutes a sensor unit, and the sensor unit is surrounded by a shield layer 23 formed with a conductive layer.

In the sensor unit, the capacitance at the intersections between the vertical wiring lines 22 and the horizontal wiring lines 32 is changed according to an applied external pressure, and the change in the capacitance at the intersections between the vertical wiring lines and the horizontal wiring lines is detected by a detecting circuit (not shown), the detecting unit. And then the externally applied pressure distribution is detected on the basis of the detecting result.

In addition, a horizontal wiring line 50 for noise detection is disposed on a surface where the horizontal wiring lines 32 of the second substrate 30 are formed. In the capacitive sensor 1 having the above structure, the vertical wiring lines 22 are not disposed at a position facing the horizontal wiring line 50 for noise detection.

As a result, the horizontal wiring line 50 for noise detection does not cross the vertical wiring lines 22, thereby signal components from the vertical wiring lines 22 are not flowed into the horizontal wiring line 50 for noise detection, and only noises delivered from the human body via the finger can be detected by the horizontal wiring line 50 for noise detection when the capacitive sensor is used as a fingerprint sensor. Accordingly, a structure of the detecting circuit for carrying out subsequent signal processing can be simplified.

In the capacitive sensor 1 having the above structure, the first substrate 20 has flexibility because of the horizontal wiring lines 22 formed on the film 21, and a surface of the first substrate 20 is to be a contacting surface of a detecting target (e.g. fingerprint of the finger). Reference numerals 24 and 33 denote insulating layers.

Accordingly, when the capacitive sensor 1 is used as a fingerprint sensor, the first substrate 20 changes the shape in response to the unevenness of the fingerprint of the finger, a detecting target, and the pressure distribution can be detected accurately.

In addition, in the capacitive sensor 1, the area of the horizontal wiring line 50 for noise detection is set to a detecting area, the area of one horizontal wiring subtracted by the sum of areas, at which the vertical wiring lines and the horizontal wiring lines overlap in a horizontal wiring 32.

Accordingly, when the capacitive sensor 1 is used as a fingerprint sensor, regardless of the change in the unevenness of the first substrate 20 (film substrate) by the fingerprint when the finger comes in contact with the sensor unit, the capacitance between the finger and the horizontal wiring lines 32 is almost equal to the capacitance between the finger and the horizontal wiring line 50 for noise detection, and the amount of noises delivered from the finger to the horizontal wiring lines 32 is almost equal to the amount of noises delivered from the finger to the horizontal wiring line 50 for noise detection.

As a result, a difference between the amount of noises delivered to each of the horizontal wiring lines and the amount of noises delivered to the horizontal wiring line for noise detection can be taken by subsequent signal processing carried out by a detecting circuit (not shown), thereby the noises delivered from a human body can be easily removed.

### Second Embodiment

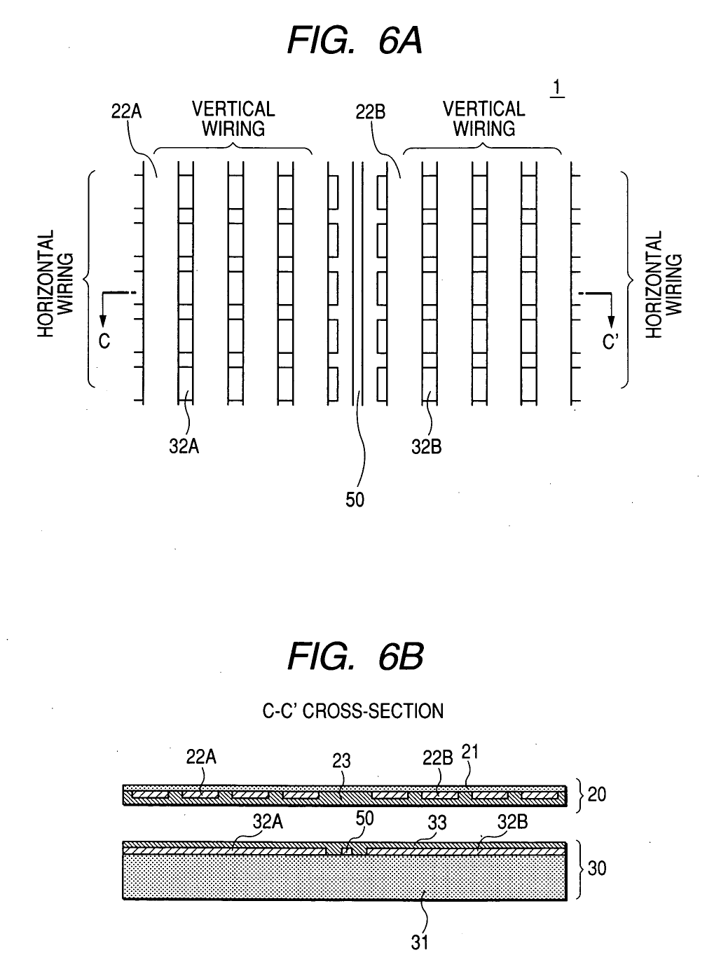

Next, FIG. 6 shows a structure of the pressure-sensitive capacitive sensor according to the second embodiment of the invention. FIG. 6A is a plan view of the sensor unit of the capacitive sensor, and FIG. 6B is a cross-sectional view taken along line C-C′ of FIG. 6A.

The capacitive sensor according to the second embodiment differs from the capacitive sensor according to the first embodiment in that vertical wiring lines and the horizontal wiring lines are divided into two areas in the first and second substrates, respectively, and are disposed in a matrix, and the horizontal wiring line 50 for noise detection is disposed at a position corresponding to an interface (i.e. central position) between the two areas in the second substrate 30 such that it does not cross the vertical wiring lines, and the rest structures are the same thereby overlapping descriptions will be omitted.

In FIG. 6, same reference numerals are applied to the same components as the capacitive sensor shown in FIG. 5. The same is applied to the following embodiments below. In FIG. 6, the first substrate 20 is divided into two areas as right and left areas in FIG. 6A, and vertical wiring lines 22A and 22B are formed in the respective areas on the film 21.

In addition, the second substrate 30 spaced apart from the first substrate 20 where the vertical wiring lines are formed by a predetermined gap, as is done in the first substrate, is divided into two areas as right and left areas thereby horizontal wiring lines 32A and 32B are formed to have matrix form with the vertical wiring lines 22A and 22B.

In addition, the horizontal wiring line 50 for noise detection is formed at an interface between the two areas in the second substrate. The area of the horizontal wiring line 50 for noise detection, as is done in the first embodiment, is set to a detecting area resulted from that a sum of areas overlapping between the vertical wiring lines 22A (or vertical wiring lines 22B) and one of the horizontal wiring lines 32A (or horizontal wiring 32B) crossing the vertical wiring lines 22A (or vertical wiring lines 22B) is subtracted from the area of the one of the horizontal wiring lines 32A (or horizontal wiring 32B).

In the present embodiment, the same effect as the first embodiment can also be obtained. In addition, the vertical wiring lines and the horizontal wiring lines are divided into two areas thereby multilayered interconnections can be designed for completing mounting single detecting circuit or two detecting circuits formed in the respective areas.

### Third Embodiment

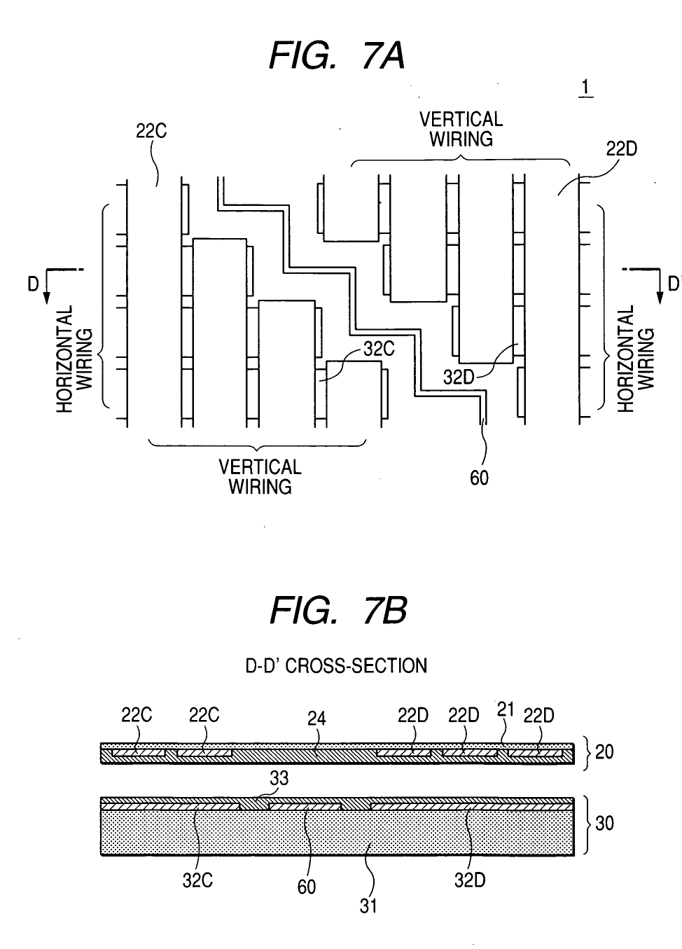

Next, FIG. 7 shows a structure of the pressure-sensitive capacitive sensor according to a third embodiment of the invention.

FIG. 7A is a plan view of the sensor unit of the capacitive sensor, and FIG. 7B is a cross-sectional view taken along line D-D′ of FIG. 7A.

The capacitive sensor according to the third embodiment differs from the capacitive sensor according to the second embodiment in that vertical wiring lines and horizontal wiring lines are divided into two areas having the inclined area used as an interface area between the two areas, thereby the wiring lines are disposed in a matrix, and the horizontal wiring line 60 for noise detection is formed at a position corresponding to the interface area between the two areas in the second substrate 30 not to cross the vertical wiring lines. Since the rest structures are the same as those of the fourth embodiment, the descriptions thereabout will be omitted.

In FIG. 7, the first substrate 20 is divided into two areas with the inclined area used as the interface area, and the vertical wiring lines 22C and 22D are formed in a way that the lengths of the vertical wiring lines are changed stepwise on the film 21.

In addition, the second substrate 30 facing the first substrate 20 where the vertical wiring lines are formed with a predetermined gap interposed therebetween, as described in the first substrate 20, is divided into two areas with the inclined area as the interface area, and the horizontal wiring lines 32C and 32D are formed in a way that the lengths of the vertical wiring lines are changed stepwise on the film 21, thereby forming a matrix.

In addition, in the second substrate 30, a horizontal wiring line 60 for noise detection is shaped like a step at the interface area between the two areas. The area of the horizontal wiring line 50 for noise detection, as described in the second embodiment, is set to a detecting area, the area of one horizontal wiring lines 32C (or horizontal wiring 32D) subtracted by the sum of the areas, at which the vertical wiring lines 22C (or vertical wiring lines 22D) and the horizontal wiring lines 32C (or horizontal wiring 32D) cross each other in a horizontal wiring 32C (or horizontal wiring lines 32D).

In the embodiment, the same effect as that of the second embodiment can be obtained.

### Fourth Embodiment

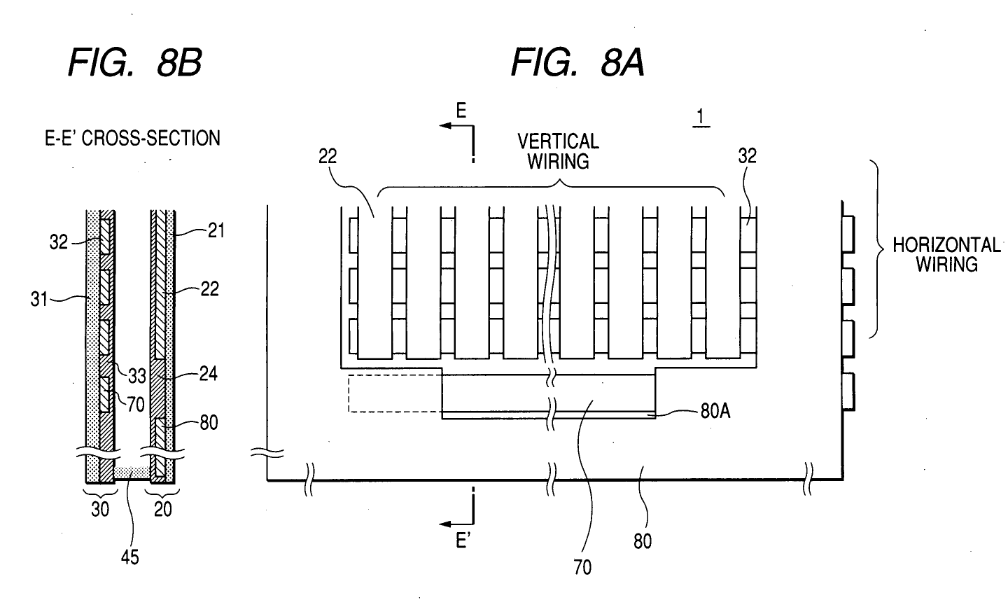

Next, FIG. 8 shows a structure of the pressure-sensitive capacitive sensor according to a fourth embodiment of the invention. FIG. 8A is a plan view of the capacitive sensor, and FIG. 8B is a cross-sectional view taken along line E-E′ of FIG. 8A.

As shown in FIG. 8, in the pressure-sensitive capacitive sensor 1 according to the fourth embodiment of the invention, like the capacitive sensor of the first embodiment, a first substrate 20 where a plurality of vertical wiring lines 22 is formed and a second substrate 30 where a plurality of horizontal wiring lines 32 is formed face each other with a space provided by the spacer 45, and the vertical wiring lines 22 and the horizontal wiring lines 32 are disposed in a matrix. The matrix portion of the vertical wiring lines 22 and the horizontal wiring lines 32 constitutes a sensor unit.

The capacitive sensor according to the fourth embodiment differs from the capacitive sensor according to the first embodiment in that a horizontal wiring line 70 for noise detection is shaped like the horizontal wiring 32 on the second substrate 30, and a shield plate 80 (shield layer) for shielding the noise is disposed with the vertical wiring lines 22 in the first substrate 20. In addition, the shield plate 80 has an opening 80A, through which the portion corresponding to the detecting area of the horizontal wiring line 70 for noise detection is exposed. Since the rest structures are the same as those of the fourth embodiment, the descriptions thereabout will be omitted.

Therefore, according to the capacitive sensor of the embodiment, in addition to the effect obtained by the first embodiment, a wiring width limit (design rule) of the horizontal wiring line 70 for noise detection can be the same as that of the horizontal wiring 32 (detecting wiring) or the vertical wiring 22 (driving wiring), thereby the cost limit can be reduced.

### Fifth Embodiment

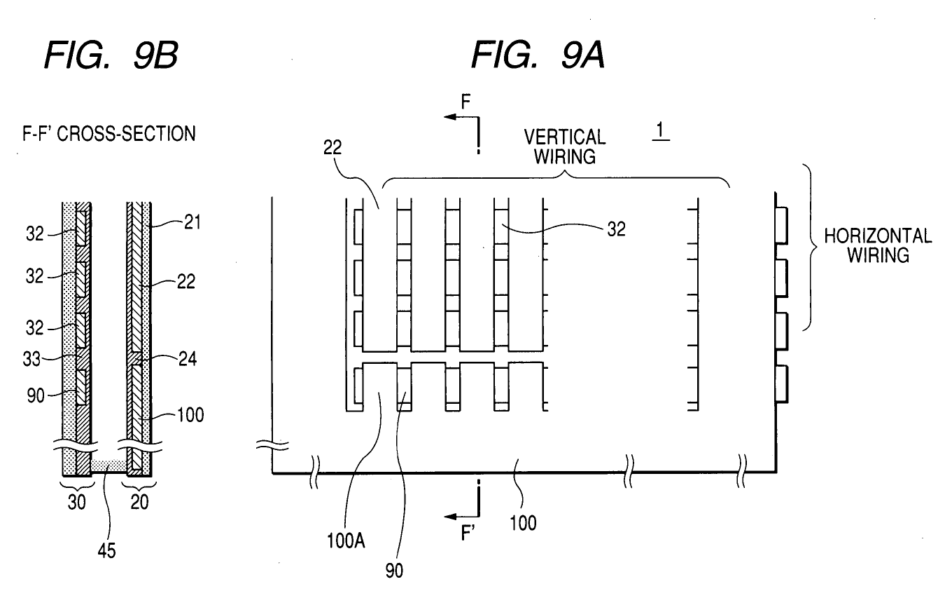

Next, FIG. 9 shows a structure of the pressure-sensitive capacitive sensor according to a fifth embodiment of the invention. FIG. 9A is a plan view of a sensor unit of the capacitive sensor, and FIG. 9B is a cross-sectional view taken along line F-F′ of FIG. 9A.

As shown in FIG. 9, in the pressure-sensitive capacitive sensor 1 according to the fifth embodiment of the invention, like the capacitive sensor of the fourth embodiment, a first substrate 20 where a plurality of vertical wiring lines 22 is formed and a second substrate 30 where a plurality of horizontal wiring lines 32 is formed face each other with a space provided by a spacer 45, and the vertical wiring lines 22 and the horizontal wiring lines 32 are disposed in a matrix. The matrix portion of the vertical wiring lines 22 and the horizontal wiring lines 32 constitutes a sensor unit.

The capacitive sensor according to the fifth embodiment differs from the capacitive sensor according to the fourth embodiment in that the shield plate 100 (shield layer) on the horizontal wiring line 90 for noise detection is shaped like a comb having the same pitch as those of the vertical wiring lines 22 to make the horizontal wiring lines 32 shaped like the portion, at which the horizontal wiring lines 32 do not cross the vertical wiring 22, at the matrix of the horizontal wiring 32 and the vertical wiring 22, that is, to make the horizontal wiring lines 32 have the comb-like convex parts 100A having the same pitch as those of the vertical wiring lines 22, thereby the area corresponding to the detecting area of the horizontal wiring line 90 for noise detection is exposed. Since the rest structures are the same as those of the fourth embodiment, the descriptions thereabout will be omitted.

Therefore, according to the capacitive sensor of the embodiment, since the horizontal wiring line for noise detection is shaped very similar to each horizontal wiring, when the capacitive sensor is used as a fingerprint sensor, in addition to the effect obtained by the fourth embodiment, the manner of unevenness of the second substrate (film substrate) near the portion of the sensor, with which the finger comes in contact, becomes equal to the manner of unevenness at the other portions of the sensor unit, thereby the amount of noises delivered to the horizontal wiring lines (detecting wiring) becomes closer to the amount of noises delivered to the horizontal wiring line for noise detection, and thus the noise-reducing effect can be improved by means of signal processing of the detecting unit. In addition, no discomfort is felt when the sensor unit is pressed by the finger.

### Sixth Embodiment

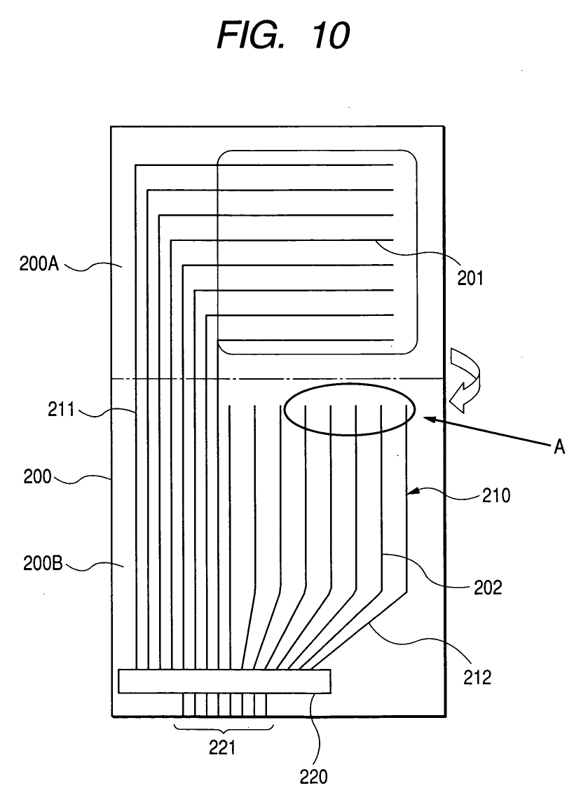

A pressure-sensitive capacitive sensor according to a sixth embodiment of the invention will be described with reference to FIGS. 10 to 12. In the pressure-sensitive capacitive sensor according to the first to fifth embodiments, the first substrate 20 where the vertical electrodes are formed and the second substrate 30 where the horizontal electrode for noise detection are disposed separately. However, in the pressure-sensitive capacitive sensor of the sixth embodiment, the first and second substrates are composed of a single flexible film substrate 200, and vertical wiring lines 201 and horizontal wiring lines 202 are formed on the flexible film substrate 200. In addition, the flexible film substrate is bent at a predetermined position to cross the horizontal wiring lines and the vertical wiring lines each other.

That is, in FIG. 10, in the capacitive sensor according to the embodiment, the single flexible film substrate 200 is divided into two areas 200A and 200B, and the vertical wiring lines 201 are formed on the upper area 200A, and the horizontal wiring lines 202 and the horizontal wiring line 210 for noise detection are formed on the lower area 200B. In addition, a circuit unit 220 including a driving circuit and a detecting circuit are formed on the lower area 200B.

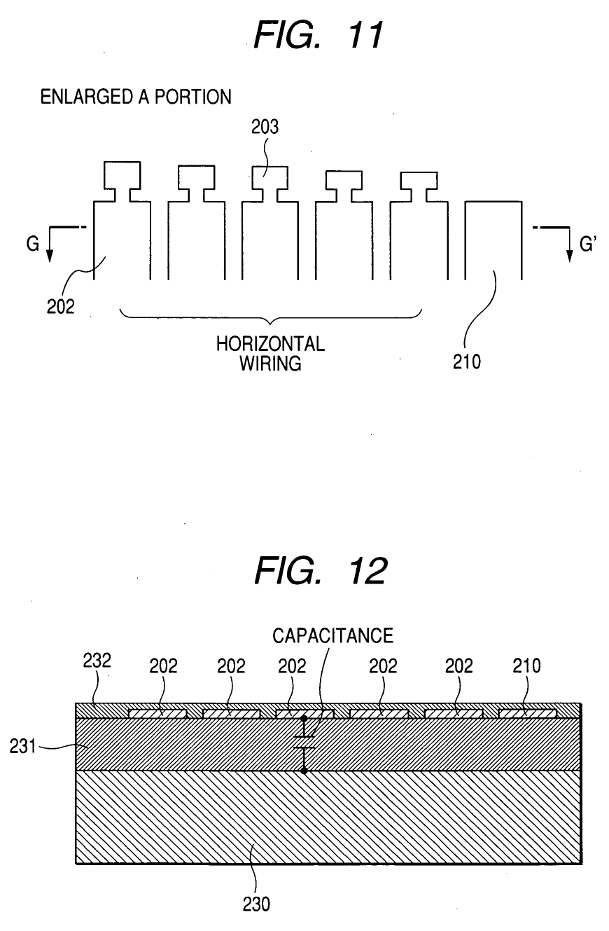

The flexible film substrate 200 is a film disposed on a reinforcement plate 230 as shown in FIG. 12, and wiring lines are formed on the film 231. In this case, FIG. 11 shows an enlarged A portion of FIG. 10, and FIG. 12 is a cross-sectional view taken along line G-G′ of FIG. 11.

The vertical wiring 201 and the horizontal wiring are connected to an input and output terminal of the circuit unit 220 by the outlet wiring 211, and the horizontal wiring 202 and the horizontal wiring line 210 for noise detection are connected to the input and output terminal by the outlet wiring 212. A reference numeral 221 denotes wiring lines for the connection with an external circuit unit.

As described above, the vertical wiring lines 201 and the horizontal wiring lines 202 can cross each other by bending the flexible film substrate 200, where the vertical wiring lines 201, the horizontal wiring lines 202, and the horizontal wiring line 210 for noise detection are formed, at an almost central position of the substrate 200.

Accordingly, the pressure-sensitive capacitive sensor can be easily assembled, and the manufacturing cost thereof can be reduced.

In addition, it is desirable that the reinforcement plate composing the flexible film substrate 200 be made of a metal and connected to the ground of the circuit unit.

Accordingly, as shown in FIG. 12, noises can be prevented from being flowed in from the metal reinforcement plate 230 via the capacitances formed between the reinforcement plate 230 and each wiring.

When the metal reinforcement plate 230 is not connected to the ground of the circuit unit, it is desirable than an auxiliary electrode 203 be provided at the horizontal wiring lines 202 as shown in FIG. 11.

It is desirable that the area of the auxiliary electrode 203 be the area of the horizontal wiring line for noise detection and all wiring lines including the outlet wiring connected to the horizontal wiring or the like subtracted by the all areas of the horizontal wiring lines and the outlet wiring connected to the horizontal wiring lines or the like for the respective horizontal wiring lines. It is needless to say that the auxiliary electrode can be disposed at any position that is not the capacitance detecting area of the capacitive sensor and has no vertical wiring lines. For example, the auxiliary electrode can be provided at a pad connected to the circuit unit (composed of an IC).

In addition, instead of the auxiliary electrode, the thickness of the outlet wiring can be changed in the middle or the outlet wiring can be bypassed.

Accordingly, the capacitances formed between the metal reinforcement plate 230 and each wiring shown in FIG. 12 make the amount of noises delivered to each of the horizontal wiring lines 202 from the reinforcement plate 230 equal to the amount of noises flowed into the horizontal wiring line 210 for noise detection from the reinforcement plate 230, thereby noises can be easily removed at a detecting circuit in the subsequent stage.

In addition, it is needless to say that the same effect as that of the first embodiment can be obtained in the embodiment.

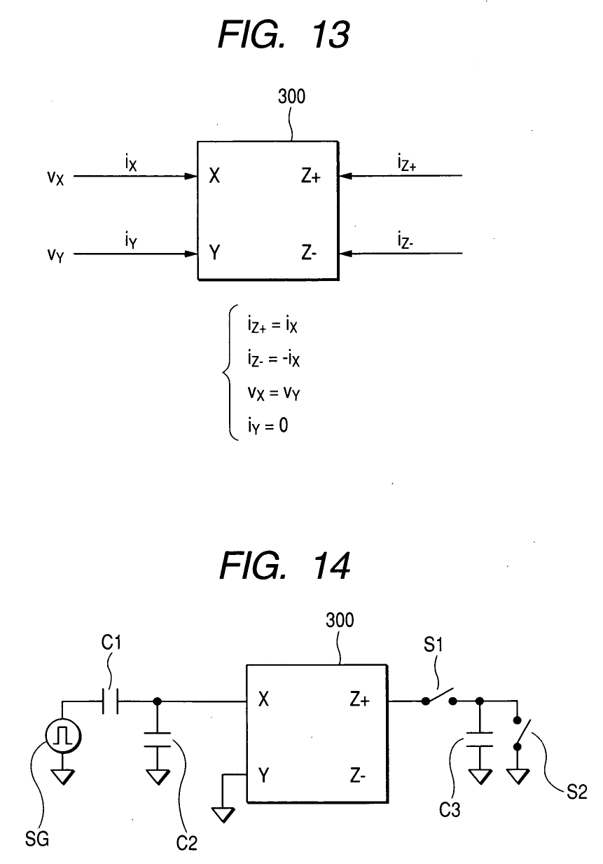

Next, an example the detecting circuit of the capacitive sensor according to the embodiments of the invention will be described. FIG. 13 shows the function of the current conveyor circuit used in the detecting circuit of the capacitive sensor according to the embodiments of the invention. In FIG. 13, the current conveyor circuit 300 is a four-terminal network circuit having input terminals X and Y and output terminals Z+ and Z−.

In the current conveyor circuit 300, in which currents flowing into the input terminals X and Y are referred to as iX and iY respectively, and currents flowing into the output terminals Z+ and Z− are referred to as iZ+ and iZ− respectively, the current flowing into the terminal X becomes equal to the current flowing into the output terminal Z+ (iZ+=iX), the voltage vX of the input terminal X becomes equal to the voltage vY of the input terminal Y (vX=vY), and they remain constant. In addition, no current flows into the input terminal Y (iY=0) and the current iX is drawn out from the output terminal Z−.

FIG. 14 shows a basic structure, in which the current conveyor circuit 300 is used in the detecting circuit of the capacitive sensor. In FIG. 14, SG denotes a signal source, more particularly, a pulse signal output from a driving circuit for driving the vertical electrode. Even though both of C1 and C2 are capacitances formed by the vertical wiring lines and the horizontal wiring lines, C1 is a capacitance to be detected by the horizontal wiring lines, and C2 is a capacitance of the other wiring lines. However, in the example, the horizontal wiring line for noise detection is not taken into account. C2 has a higher value than C1 and the maximum value of (the maximum value of C1)×Ln when the number of vertical wiring lines is n. C3 is a capacitance for detecting-voltage maintenance, and S2 and S2 are switches. S1 is turned off when the sensor does not detect the fingerprint and turned on when the sensor detects the fingerprint. S2 is a reset switch for discharging remaining charges when the fingerprint is detected.

In the above structure, when the fingerprint is detected, the switch S2 is turned on, and thus the remaining charges of the capacitance C3 for signal-detecting are discharged. And then, the switch S2 is turned off, and the switch S1 is turned on. In this case, if a pulse signal is output from the SG and a signal corresponding to the unevenness of the fingerprint is input via the capacitance for signal-detecting C1, a current corresponding to the detected signal flows into the input terminal X of the current conveyor circuit, and a current having the same value as the detected current flows into the capacitance for detecting-voltage maintenance via the switch S1 from the output terminal Z+, and thus the signal voltage is maintained.

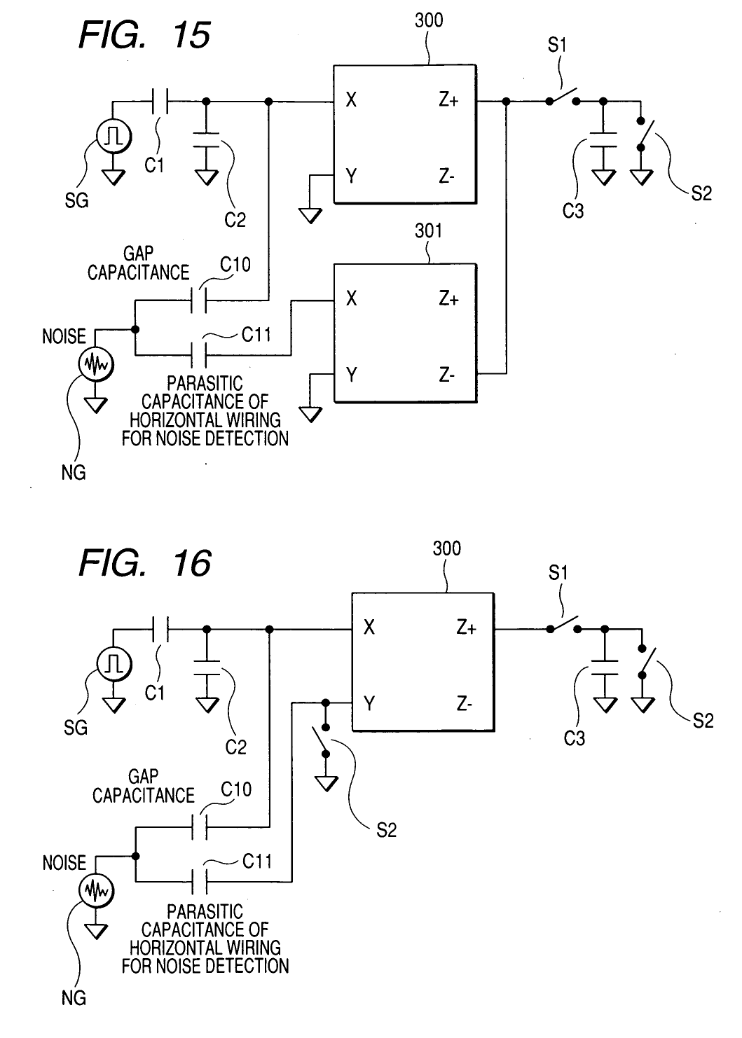

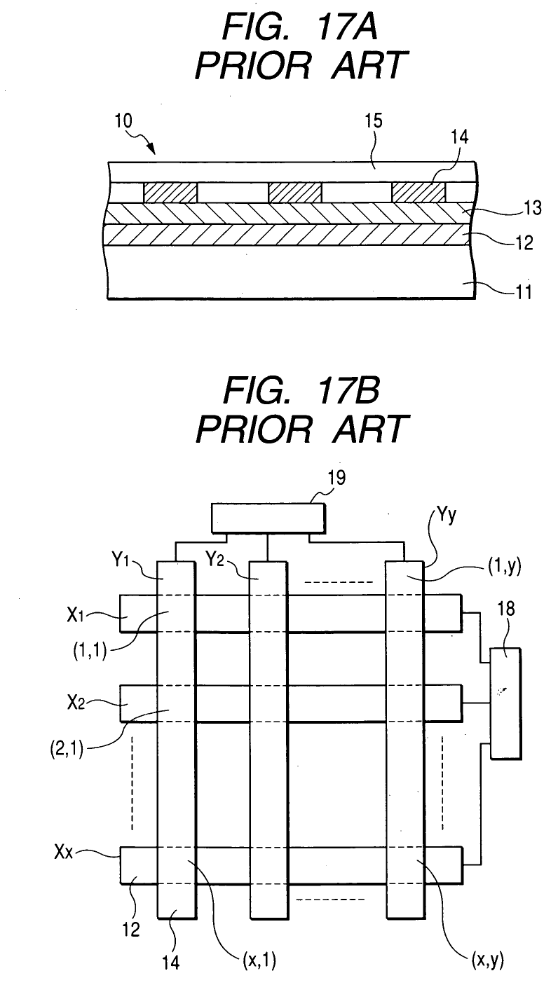

Next, FIGS. 15 and 16 show examples of the detecting circuits using the current conveyor circuit taking into account a case that noises are input via the gap capacitance C10 formed between the finger and the horizontal electrodes and the parasitic capacitance C11 formed between the finger and the horizontal wiring line for noise detection when the fingerprint is detected. In FIGS. 15 and 16, NG is a source of noise, more particularly, noises flowed in from the finger when the finger comes in contact with the sensor unit of the capacitive sensor. The detecting circuit shown in FIG. 15 is operated in a current mode. In FIG. 15, another current conveyor circuit 301 is provided in addition to the circuit structure of FIG. 14.

The output of the noise source NG is connected to the input terminal X of the current conveyor circuit 300 via the gap capacitance C10 and to the input terminal X of the current conveyor circuit 300 via the parasitic capacitance C11. The output terminal Z+ of the current conveyor circuit 300 and the output terminal Z− of the current conveyor circuit 301 are connected with each other.

In FIG. 15, the noise current output from the noise source NG flows into the input terminal X of the current conveyor circuit 300 via the gap capacitance C10 and into the input terminal X of the current conveyor circuit 301 via the parasitic capacitance C11. As a result, the common currents flow into the input terminals of the current conveyor circuits 300 and 301, thereby the currents reversely flow through the output terminal Z+ of the current conveyor circuit 300 and the output terminal Z− of the current conveyor circuit 301 at the same current value, and noises can be removed from the output terminal of the detecting circuit.

Next, FIG. 16 shows an example of the detecting circuit operated in a voltage mode using the current conveyor circuit. In the detecting circuit shown in FIG. 16, comparing with the detecting circuit shown in FIG. 15, the current conveyor circuit 301 is removed, and the output of the noise source NG is connected to the input terminal Y of the current conveyor circuit 300 via the parasitic capacitance C11 of the horizontal wiring line for noise detection.

In the above structure, the noise currents output from the noise source NG flow into the input terminal X of the current conveyor circuit 300 because the input terminal X is in a low impedance, however, no currents flow into the input terminal Y because the input terminal Y is in a high impedance. As a result, the charged voltage of the gap capacitance C10 due to the noise currents and the charged voltage of the horizontal wiring line for noise detection have reversed polarities each other, thereby noises can be removed from the input terminal of the current conveyor circuit 300.

As described above, according to the invention, a pressure-sensitive capacitive sensor capable of easily removing noises delivered from a human body can be obtained.

1. A pressure-sensitive capacitive sensor, comprising:
a sensor unit including a first substrate where a plurality of vertical wiring lines is formed and a second substrate where a plurality of horizontal wiring lines is formed, the first and second substrates being disposed in a matrix and facing each other with a gap interposed between the first and second substrates, and capacitances at intersections between the vertical wiring lines and the horizontal wiring lines changed in response to an external pressure; and
a detecting unit for detecting a change in the capacitances at the intersections between the vertical wiring lines and the horizontal wiring lines, and detecting an externally applied pressure distribution based on the detecting result,
wherein a horizontal wiring line for noise detection is disposed on a surface where the horizontal wiring lines of the second substrate are formed.

2. The pressure-sensitive capacitive sensor according to claim 1,
wherein the vertical wiring lines are not disposed at a position facing the horizontal wiring line for noise detection.

3. The pressure-sensitive capacitive sensor according to claim 1,
wherein the first substrate has flexibility and use a surface of the first substrate as a contacting surface with a detecting target.

4. The pressure-sensitive capacitive sensor according to claim 3,
wherein the area of the horizontal wiring line for noise detection is equal to a detecting area, an area of one horizontal wiring line subtracted by the sum of areas, at which the vertical wiring lines and the horizontal wiring lines overlap in a horizontal wiring line.

5. The pressure-sensitive capacitive sensor according to claim 4,
wherein the horizontal wiring line for noise detection is shaped like the horizontal wiring lines, and a shield plate for shielding the noise is disposed on the horizontal wiring line for noise detection, and the shield plate is disposed in the first substrate and has an opening through which an area corresponding to the detecting area of the horizontal wiring line for noise detection is exposed.

6. The pressure-sensitive capacitive sensor according to claim 5,
wherein the shield plate on the horizontal wiring line for noise detection is shaped like a comb having the same pitch as those of the vertical wiring lines in order to have the same shape as that of the area where the horizontal wiring line and the vertical wiring line do not cross each other in the matrix of the horizontal and vertical wiring lines, and an area corresponding to the detecting area of the horizontal wiring line for noise detection is exposed.

7. The pressure-sensitive capacitive sensor according to claim 6,
wherein the first and second substrates are composed of a single flexible film substrate, the horizontal and vertical wiring lines are formed on the flexible film substrate, and the flexible film substrate is bent at a predetermined position to make the horizontal wiring lines and the vertical wiring lines cross each other.
